(19) United States
(12) Patent Application Publication
(10) Pub. No.: US 2020/0126887 A1
(43) Pub. Date: Apr. 23, 2020

(54) THIN LINE DAM ON UNDERFILL MATERIAL TO CONTAIN THERMAL INTERFACE MATERIALS

(71) Applicant: Intel Corporation, Santa Clara, CA (US)

(72) Inventors: Ziyin Lin, Chandler, AZ (US); Jingyi Huang, Chandler, AZ (US); Peng Li, Chandler, AZ (US); Marco Aurelio Cartas, Chandler, AZ (US); Nisha Ananthakrishnan, Chandler, AZ (US)

(73) Assignee: Intel Corporation, Santa Clara, CA (US)

(21) Appl. No.: 16/164,120

(22) Filed: Oct. 18, 2018

(51) Int. Cl. H01L 23/373; H01L 23/42

(52) U.S. Cl. CPC H01L 23/3736; H01L 23/42

(57) ABSTRACT

An apparatus is provided which comprises: a package substrate, an integrated circuit device coupled with contacts on a surface of the package substrate, underfill between the integrated circuit device and the surface of the package substrate, thermal interface material on a surface of the integrated circuit device opposite the package substrate, a heat spreader in contact with the thermal interface material, and a material on a fillet of the underfill, the material adjacent to the thermal interface material. Other embodiments are also disclosed and claimed.

### BACKGROUND

As computing devices continue to get smaller and more powerful, thermal management solutions need to evolve to meet new challenges. Passive thermal solutions, such as integrated heat spreaders, are commonly coupled with integrated circuit devices, through the use of a thermal interface material, to dissipate heat. Thermal interface materials can be semi-solid or liquid, such as polymers or solder, for example. If thermal interface materials are allowed to migrate from the surface of the integrated circuit device, there could be significantly decreased thermal performance. A bleed-out of thermal interface material can also potentially contact adjacent die-side components, creating a risk of component failures.

Conventionally, solutions for preventing bleed-out of thermal interface material have included placing sealant on the integrated circuit device or incorporating fins into the integrated heat spreader to contain thermal interface material. However, sealant on the integrated circuit device may provide areas of inadequate thermal conductivity and fins in the integrated heat spreader may add cost and create new keep out zones on the printed circuit board. Therefore, there is a need for thermal interface material containment that does not risk thermal degradation or require additional keep out zones.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of an example integrated circuit device package with a thin line dam on underfill material to contain thermal interface materials, according to some embodiments,

FIG. 2 illustrates a cross-sectional view of another example integrated circuit device package with a thin line dam on underfill material to contain thermal interface materials, according to some embodiments,

FIG. 3 illustrates a cross-sectional view of a partially formed integrated circuit device package suitable for implementing a thin line dam on underfill material to contain thermal interface materials, according to some embodiments,

FIG. 4 illustrates a cross-sectional view of a partially formed integrated circuit device package suitable for implementing a thin line dam on underfill material to contain thermal interface materials, according to some embodiments,

FIG. 5 illustrates a cross-sectional view of a partially formed integrated circuit device package suitable for implementing a thin line dam on underfill material to contain thermal interface materials, according to some embodiments,

FIG. 6 illustrates an overhead view of a partially formed integrated circuit device package suitable for implementing a thin line dam on underfill material to contain thermal interface materials, according to some embodiments,

FIG. 7 illustrates an overhead view of a partially formed integrated circuit device package suitable for implementing a thin line dam on underfill material to contain thermal interface materials, according to some embodiments,

FIG. 8 illustrates a cross-sectional view of a partially formed integrated circuit device package suitable for implementing a thin line dam on underfill material to contain thermal interface materials, according to some embodiments,

FIG. 9 illustrates a cross-sectional view of an example integrated circuit device package with a thin line dam on underfill material to contain thermal interface materials, according to some embodiments,

FIG. 10 illustrates a cross-sectional view of a system with an example integrated circuit device package with a thin line dam on underfill material to contain thermal interface materials, according to some embodiments,

FIG. 11 illustrates a flowchart of a method of forming an integrated circuit device package with a thin line dam on underfill material to contain thermal interface materials, in accordance with some embodiments, and

FIG. 12 illustrates a smart device or a computer system or a SoC (System-on-Chip) which includes an integrated circuit device package with a thin line dam on underfill material to contain thermal interface materials, according to some embodiments.

### DETAILED DESCRIPTION

A thin line dam on underfill material to contain thermal interface materials is generally presented. In this regard, embodiments of the present disclosure enable a material on a fillet of the underfill to prevent bleed-out, or other unwanted expansion, of the thermal interface material. In this way, a barrier can be added during the manufacturing process that doesn't add significant cost or additional keep out zones. One skilled in the art would appreciate that this approach may enable more reliable manufacturing with better thermal performance and smaller footprints.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicates that different instances of like objects are being referred to, and is not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” right “front,” “back,” “top,” “bottom,” “over,” “under,” and the like in the description and in the claims, if any, are used for descriptive purposes and not necessarily for describing permanent relative positions.

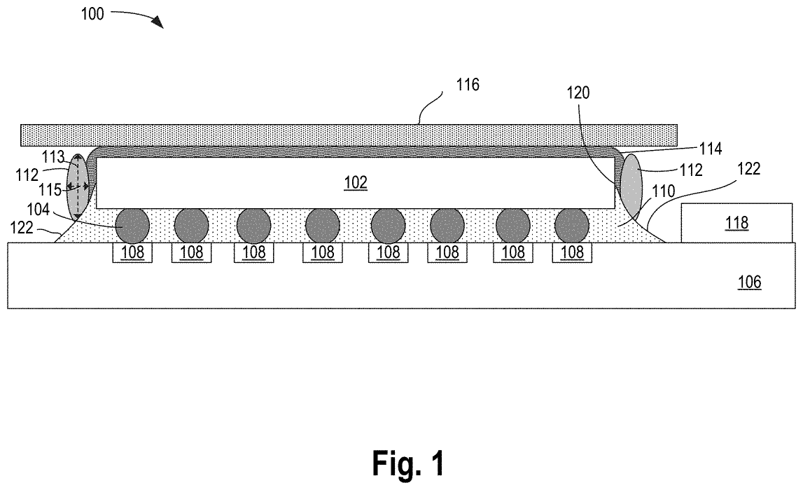

FIG. 1 illustrates a cross-sectional view of an example integrated circuit device package with a thin line dam on underfill material to contain thermal interface materials, according to some embodiments. As shown, package 100 includes integrated circuit device 102, device contacts 104, package substrate 106, substrate pads 108, underfill 110, thin line material 112, thermal interface material 114, heat spreader 116, die side component 118, device edge 120, and underfill fillet 122. In some embodiments, package 100 may represent a computing or communication device. Package 100 may be integrated as part of any type of system, including, but not limited to, a personal computing, mobile, desktop, laptop, or server system.

Integrated circuit device 102 may represent any type of device including, but not limited to, a processor, a controller, a field programmable gate array (FPGA), etc. Device contacts 104 may represent solder balls, such as, for example microbumps. Substrate pads 108 may represent conductive contacts, such as solder pads, etc. to route input/output signals, power, ground, etc. to and from integrated circuit device 102. Integrated circuit device 102 may couple with substrate 106 through any known method including, but not limited to soldering. In some embodiments, each device contact 104 is coupled with a substrate pad 108. Package substrate 106 may include one or more die side components 118, including, but not limited to, sensors, memory devices, passive devices, etc, which may be coupled with device 102 through electrical routing (not shown). In some embodiments, die side components 118 may be sited relatively, close, for example within 1 cm, to integrated circuit device 102.

In some embodiments, underfill 110 represents a cured material that has been deposited between integrated circuit device 102 and package substrate 106, to provide mechanical support and stability. In some embodiments, underfill 110 is an epoxy underfill, though other underfill materials may be used. In some embodiments, underfill 110 may include underfill fillet 122, which may comprise a concave surface that extends beyond device edge 120 to the surface of package substrate 106. While shown as extending to a point about midway along device edge 120, underfill fillet 122 may extend along device edge 120 to a greater or lesser extent.

As shown in more detail hereinafter, thin line material 112 protrudes from underfill fillet 122 to contain thermal interface material 114. While shown as being more tall than wide, thin line material 112 may have other proportions. Also, while shown as having a vertical orientation, thin line material may be oriented at any angle relative to package substrate 106. In some embodiments, thin line material 112 includes a longitudinal axis oriented at a sixty-degree angle to package substrate 106. To be dispensed on, and adhere to underfill fillet 122, thin line material 112 may advantageously have certain properties. For example, thin line material 112 may have a high thixotropic index and appropriate viscosity to ensure dispensability and desired geometry on underfill fillet 122, i.e. to ensure thin line material 112 sets up in place and resists flowing down underfill fillet 122. In some embodiments, thin line material 112 has a viscosity of between 50 and 70 pascal-seconds at room temperature. In some embodiments, thin line material 112 has a viscosity of between 20 and 100 pascal-seconds at room temperature. In some embodiments, thin line material 112 has a thixotropic index of greater than 2.7. In some embodiments, thin line material 112 has a thixotropic index of greater than 1.5.

Additionally, thin line material 112 may have strong adhesion to epoxy, chemical resistance to solder, and cure kinetics to match thermal interface material 114. While other materials may have the properties suitable for use in thin line material 112, in some embodiments, a resin, such as a polymer resin, may be used with or without fillers. In some embodiments, polymer resins include, but are not limited to, silicone, polyurethane, or acrylic elastomer or elastomer modified epoxy. In some embodiments, resin fillers include, but are not limited to, silica, oxides (such as titanium oxide or zinc oxide), alumina, or nitrides (such as alumina nitride). In some embodiments, thin line material 112 is a silicone resin of the formula RₙSiXₘO_{y}, where R is a non-reactive substituent, such as Methyl (Me) or Phenyl (Ph), and X is a functional group, such as Hydrogen (H), Hydroxyl group (OH), Chlorine (Cl) or Alkoxy group (OR). In some embodiments, thin line material 112 is a silicone resin with a titanium oxide filler at a concentration of between 10-20% by volume.

Thermal interface material 114 may be a solder, polymer or polymer composite, liquid metal, or phase change material, for example. In some embodiments, thermal interface material 114 has a thermal conductivity of greater than 1 watt per meter-kelvin (W/(mK)). In some embodiments, thermal interface material 114 may migrate over device edge 120 and contact underfill fillet 122 between device edge 120 and thin line material 112.

Heat spreader 116 may be a metal or other thermally conductive solid material to spread heat from integrated circuit device 102. Heat spreader 116 may include fins (not shown) and may include adhesive or fasteners to further secure heat spreader 116 to package substrate 106.

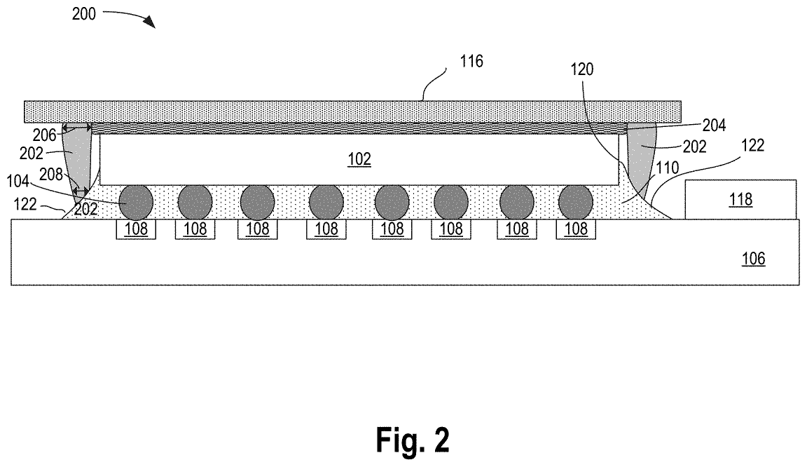

FIG. 2 illustrates a cross-sectional view of another example integrated circuit device package with a thin line dam on underfill material to contain thermal interface materials, according to some embodiments. As shown, package 200 includes integrated circuit device 102, device contacts 104, package substrate 106, substrate pads 108, underfill 110, thin line material 202, thermal interface material 204, heat spreader 116, die side component 118, device edge 120, and underfill fillet 122. As shown, thin line material 202 may contact heat spreader 116. In some embodiments, the application of heat spreader 116 may deform thin line material 202 such that thin line material 202 has a greater width at the junction with heat spreader 116 than at the junction with underfill fillet 122. In some embodiments, thin line material 202 has a transverse width that may vary between 100 um and 400 um. Thin line material 202 may advantageously have a low modulus and proper elastic deformability to ensure a good seal with heat spreader 116. In some embodiments, thin line material 202 has a modulus of less than 10 megapascals at room temperature. In some embodiments, thin line material 202 has a modulus of less than 900 megapascals at room temperature.

Thermal interface material 204 may be a semi-solid thermal interface material, such as a polymer or polymer composite, in some embodiments, and may extend out over device edge 120 adjacent thin line material 202, but not down to contact underfill fillet 122. In some embodiments, for example where the curing of thermal interface material 204 doesn't result in outgassing, thin line material 202 may form a seal with heat spreader 116 around all edges of integrated circuit device 102. In some embodiments, for example where the curing of thermal interface material 204 does result in outgassing, thin line material 202 may fluctuate in height between being in contact with, and being separated from, heat spreader 116 as thin line material 202 surrounds integrated circuit device 102.

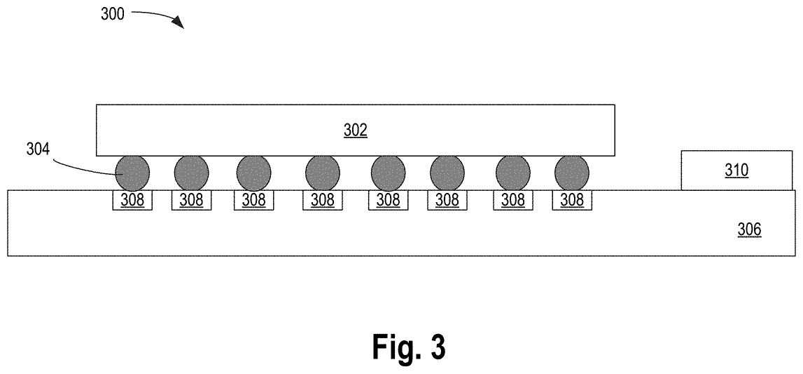

FIG. 3 illustrates a cross-sectional view of a partially formed integrated circuit device package suitable for implementing a thin line dam on underfill material to contain thermal interface materials, according to some embodiments. As shown, assembly 300 includes integrated circuit device 302, device contacts 304, package substrate 306, substrate pads 308, and die side component 310. While shown as including one die side component 310, any number and type of die side components may be present, such as resistors, capacitors, transistors, etc. Integrated circuit device 302 and die side component 310 may be affixed (i.e. soldered) to package substrate 306 in either order and may be reflowed simultaneously or separately. In some embodiments, assembly 300 is preheated to between 70° C. and 125° C. to minimize distortion in package substrate 306. Integrated circuit device 302 may represent any type of integrated circuit device, including, but not limited to, a processor, controller, programmable chip, system on a chip, etc.

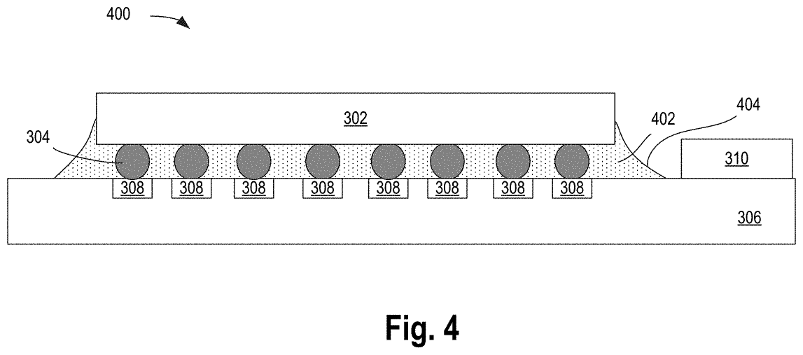

FIG. 4 illustrates a cross-sectional view of a partially formed integrated circuit device package suitable for implementing a thin line dam on underfill material to contain thermal interface materials, according to some embodiments. As shown, assembly 400 includes integrated circuit device 302, device contacts 304, package substrate 306, substrate pads 308, die side component 310, underfill 402, and underfill fillet 404. Underfill 402 may be formed between integrated circuit device 302 and package substrate 306 by any known methods, including, but not limited to, by flowing and curing epoxy. Underfill 402 may extend upward along one or more edges of integrated circuit device 302 to a greater or lesser extent than as shown. In some embodiments, underfill fillet 404 may be present without any additional processing, while in other embodiments, underfill fillet 404 may result from a scraping or removal of excess underfill 402. In some embodiments, underfill 402 is dispensed on a corner or in a line along an edge of integrated circuit device 302. Assembly 400 may then be heated to a temperature in the range of 125° C. to 165° C. to flow the underfill. In some embodiments, capillary action then takes over to absorb the underfill under integrated circuit device 302. In some embodiments, the temperature is held until underfill 402 is cured. In some embodiments, a fast-curing underfill 402 may be cured in less than e minutes, while in other embodiments, underfill 402 may take over an hour to cure.

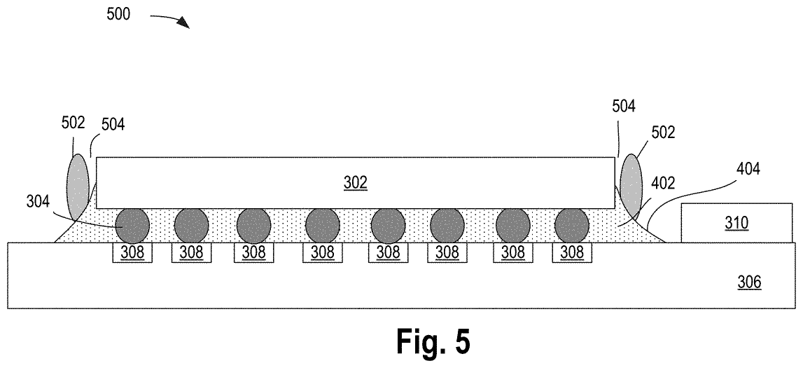

FIG. 5 illustrates a cross-sectional view of a partially formed integrated circuit device package suitable for implementing a thin line dam on underfill material to contain thermal interface materials, according to some embodiments. As shown, assembly 500 includes integrated circuit device 302, device contacts 304, package substrate 306, substrate pads 308, die side component 310, underfill 402, underfill fillet 404, thin line material 502, and gaps 504. In some embodiments, thin line material 502 has a height equal to at least one edge of integrated circuit device 302. Gaps 504 between an edge of integrated circuit device 302 and thin line material 502 may serve as a reservoir to contain migrating thermal interface material as shown hereinafter. In some embodiments, gaps 504 may range from between 300 um and 900 um. In some embodiments, gaps 504 may range from between 100 um and 2000 um. Thin line material 502 may be deposited by any known method, including, but not limited to, a pressurized dispenser where the thixotropic properties of thin line material 502 may allow it to be dispensed as a less viscous liquid state and quickly transition to a more viscous gel state.

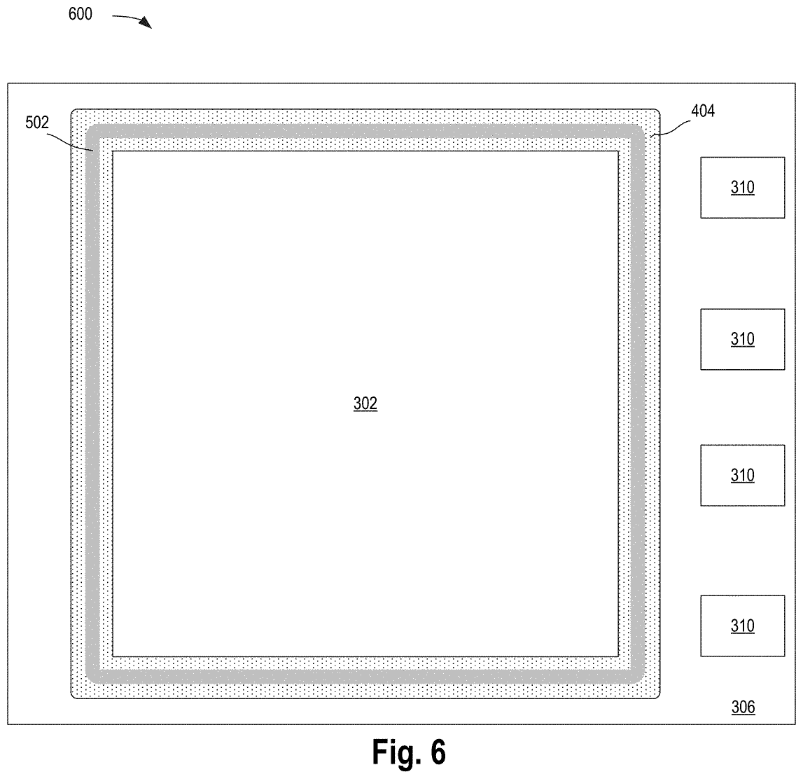

FIG. 6 illustrates an overhead view of a partially formed integrated circuit device package suitable for implementing a thin line dam on underfill material to contain thermal interface materials, according to some embodiments. As shown, assembly 600 includes integrated circuit device 302, package substrate 306, die side components 310, underfill fillet 404, and thin line material 502. While shown as surrounding all edges of integrated circuit device 302, in some embodiments, thin line material 502 may surround fewer than all edges of integrated circuit device 302. In some embodiments, thin line material 502 extends a longitudinal length equal to at least one edge of integrated circuit device 302. While shown as having a relatively constant width, in some embodiments, thin line material 502 may vary in width around integrated circuit device 302.

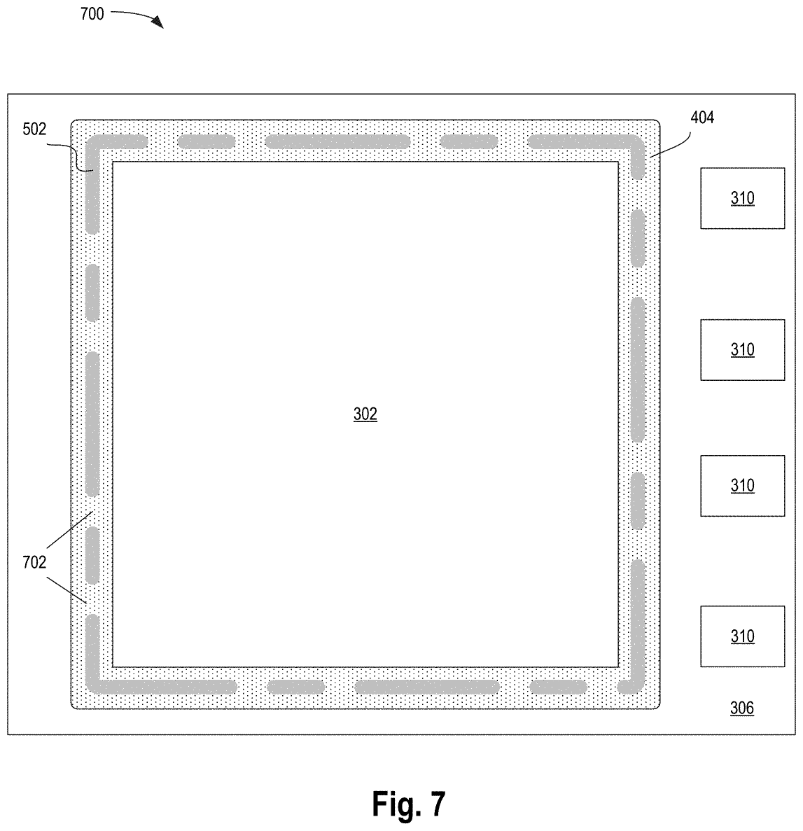

FIG. 7 illustrates an overhead view of a partially formed integrated circuit device package suitable for implementing a thin line dam on underfill material to contain thermal interface materials, according to some embodiments. As shown, assembly 700 includes integrated circuit device 302, package substrate 306, die side components 310, underfill fillet 404, thin line material 502, and spacings 702. In some embodiments, spacings 702 may be included in thin line material 502, for example to allow for outgassing from thermal interface material. While shown as being included along all edges of integrated circuit device 302, in some embodiments, spacings 702 are present along fewer than all edges of integrated circuit device 302. In some embodiments, spacings 702 form a plurality of discrete segments of thin line material 502 spaced apart along at least one edge of integrated circuit device 302 by less than 100 um.

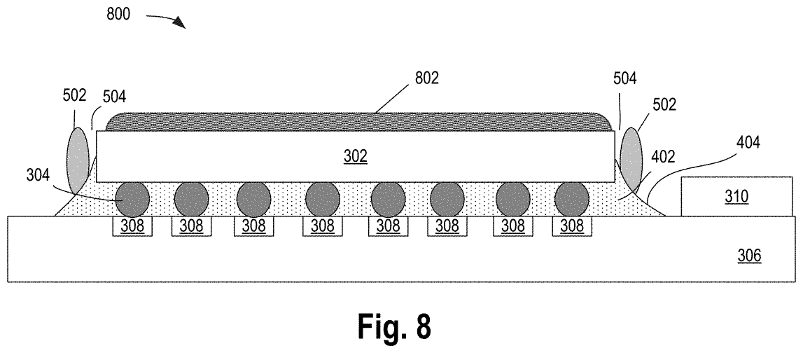

FIG. 8 illustrates a cross-sectional view of a partially formed integrated circuit device package suitable for implementing a thin line dam on underfill material to contain thermal interface materials, according to some embodiments. As shown, assembly 800 includes integrated circuit device 302, device contacts 304, package substrate 306, substrate pads 308, die side component 310, underfill 402, underfill fillet 404, thin line material 502, gaps 504, and thermal interface material 802. In some embodiments, thermal interface material 802 may be a solder, a polymer or polymer composite, a liquid metal, phase change material or another highly thermally conductive material. Thermal interface material 802 may be deposited by any known method, including, but not limited to, spraying, pouring, or placing. When deposited, thermal interface material 802 may cover a top surface of integrated circuit device 302 to a greater or lesser extent than as shown.

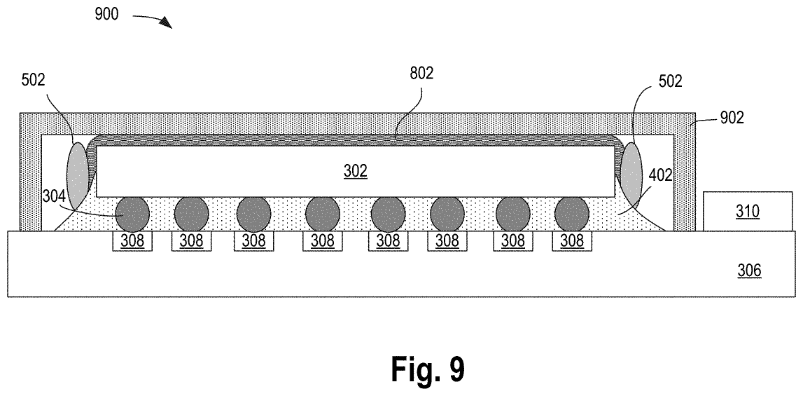

FIG. 9 illustrates a cross-sectional view of an example integrated circuit device package with a thin line dam on underfill material to contain thermal interface materials, according to some embodiments. As shown, package 900 includes integrated circuit device 302, device contacts 304, package substrate 306, substrate pads 308, die side component 310, underfill 402, thin line material 502, thermal interface material 802, and heat spreader 902. In some embodiments, heat spreader 902 may include one or more orthogonal extensions (or extensions extend at some other angle) that contact package substrate 306 and may be affixed thereon with sealant (not shown). In some embodiments, heat spreader 902 may be a plate or block of material having high thermal conductivity, such as copper, aluminum, or diamond. In some embodiments, composite materials may be used for heat spreader 902, such as the metal matrix composites (MMCs) copper-tungsten, Al SiC (silicon carbide in aluminium matrix), Dymalloy (diamond in copper-silver alloy matrix), and E-Material (beryllium oxide in beryllium matrix). In some embodiments, a downward pressure applied to heat spreader 902 may force thermal interface material 802 to migrate over the edges of integrated circuit device 302 and into gaps 504. In some embodiments, thermal interface material 802 extends beyond an edge of integrated circuit device 302 and contacts a portion of underfill 402 between an edge of integrated circuit device 302 and thin line material 502, but is absent from an exterior side of thin line material 502 opposite integrated circuit device 302.

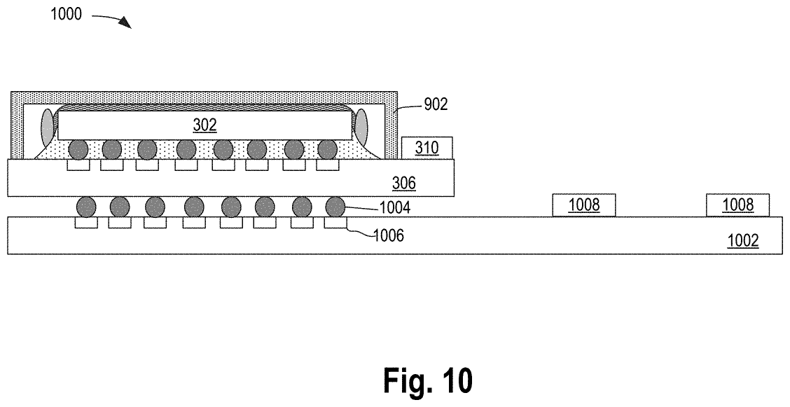

FIG. 10 illustrates a cross-sectional view of a system with an example integrated circuit device package with a thin line dam on underfill material to contain thermal interface materials, according to some embodiments. As shown, system 1000 includes integrated circuit device 302, package substrate 306, die side component 310, heat spreader 902, system board 1002, package contacts 1004, system board contacts 1006, and system board components 1008.

In some embodiments, system board 1002 represents a printed circuit board of any number of layers. System board 1002 may include one or more system board components 1008, including, but not limited to, processors, controllers, sensors, memory devices, passive devices, etc, which may be coupled with device 302 through electrical routing (not shown). Package contacts 1004 may represent solder balls, such as, for example a ball grid array (BGA) arrangement. System board pads 1006 may represent conductive contacts, such as socket pads, microbumps, etc. to route input/output signals, power, ground, etc. to and from integrated circuit device 302. In some embodiments, package 900 is soldered to system board 1002, while in other embodiments package 900 may be affixed to system board 1002 through a socket or another non-permanent connection. While shown as having a similar pitch and ball size as device contacts 304, package contacts 1004 may have a significantly coarser pitch and larger ball size than device contacts 304. In some embodiments, package contacts 1004 have a ball size twice that of device contacts 304. In some embodiments, package contacts 1004 have a nominal ball diameter of greater than 0.5 mm.

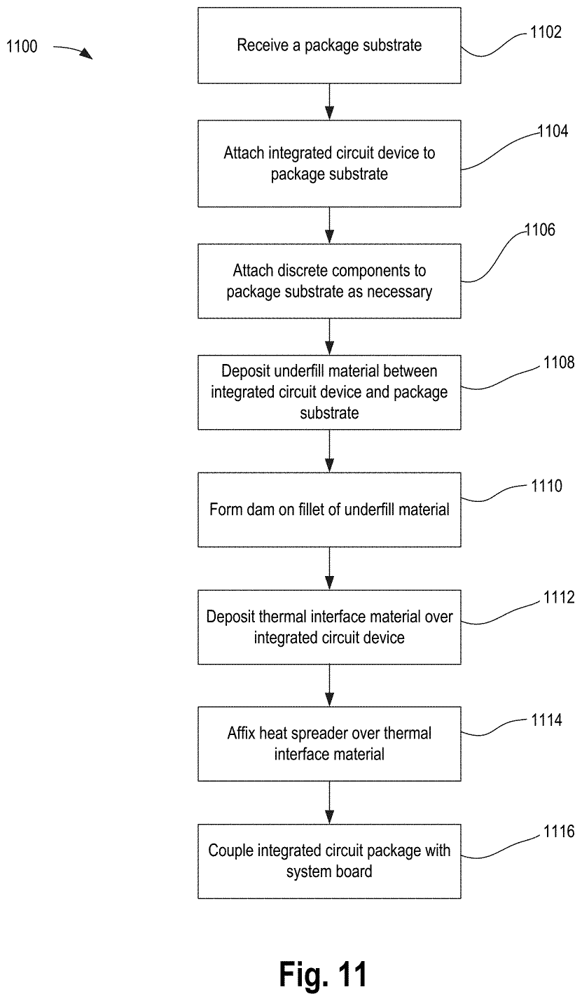

FIG. 11 illustrates a flowchart of a method of forming an integrated circuit device package with a thin line dam on underfill material to contain thermal interface materials, in accordance with some embodiments. Although the blocks in the flowchart with reference to FIG. 11 are shown in a particular order, the order of the actions can be modified. Thus, the illustrated embodiments can be performed in a different order, and some actions/blocks may be performed in parallel. Some of the blocks and/or operations listed in FIG. 11 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 1100 begins with receiving (1102) a package substrate. In some embodiments, package substrate 306 may include organic and/or inorganic layers. In some embodiments, package substrate 306 may include a printed circuit board. Next, an integrated circuit device may be attached (1104) to the package substrate. In some embodiments, integrated circuit device 302 may be a processor. In some embodiments, integrated circuit device 302 may be soldered to package substrate 306.

Then, discrete components may be attached (1106) to the package substrate. In some embodiments, die side component 310 may include passive components. In some embodiments, die side component 310 may include active components. Next, underfill material is deposited (1108) between the integrated circuit device and package substrate. In some embodiments, underfill 402 may include a concave underfill fillet 404 that extends from an edge of integrated circuit device 302.

The method continues with forming (1110) a dam on a fillet of the underfill material. In some embodiments, thin line material 502 surrounds all edges of integrated circuit device 302. In some embodiments, material 502 includes discrete segments and/or fluctuations in height around integrated circuit device 302. Next, thermal interface material may be deposited (1112) over the integrated circuit device. In some embodiments, thermal interface material 802 may be applied to integrated circuit device 302 as a semi-solid, such as a paste or grease. In some embodiments, thermal interface material 802 may be applied to integrated circuit device 302 as a liquid.

Then a heat spreader is affixed (1114) over the thermal interface material. In some embodiments, heat spreader 902 forces thermal interface material to migrate over an edge of integrated circuit device 302 adjacent to thin line material 502. Finally, the integrated circuit device package is coupled (1116) with a system board. In some embodiments, package 900 may be inserted into a socket of system 1000.

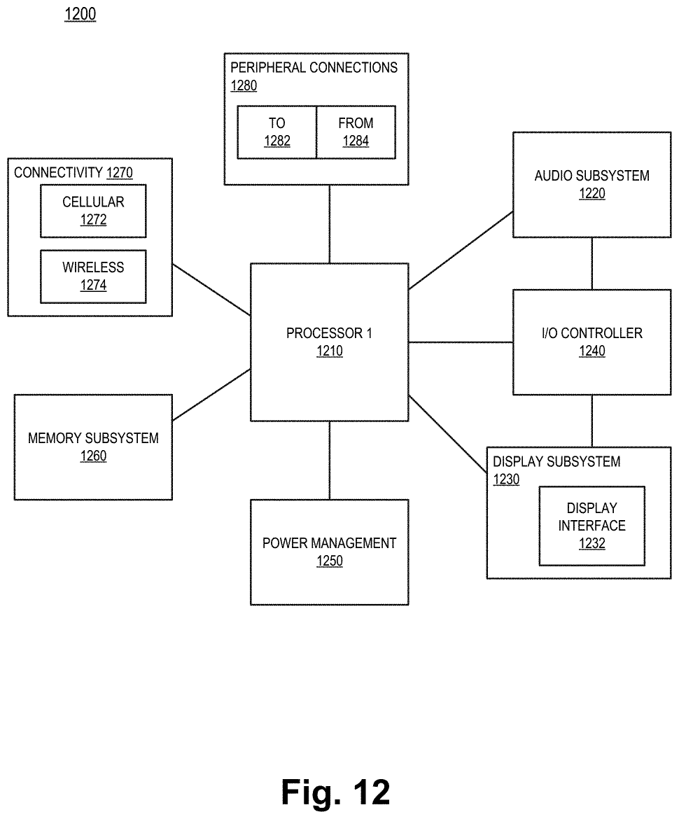

FIG. 12 illustrates a smart device or a computer system or a SoC (System-on-Chip) 1200 which includes an integrated circuit device package with a thin line dam on underfill material to contain thermal interface materials, according to some embodiments. In some embodiments, computing device 1200 represents a mobile computing device, such as a computing tablet, a mobile phone or smart-phone, a wireless-enabled e-reader, or other wireless mobile device. It will be understood that certain components are shown generally, and not all components of such a device are shown in computing device 1200. In some embodiments, one or more components of computing device 1200, for example processor 1210 and/or connectivity 1270, include a package with a thin line dam on underfill material to contain thermal interface materials as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 1200 includes a first processor 1210. The various embodiments of the present disclosure may also comprise a network interface within 1270 such as a wireless interface so that a system embodiment may be incorporated into a wireless device, for example, cell phone or personal digital assistant.

In one embodiment, processor 1210 can include one or more physical devices, such as microprocessors, application processors, microcontrollers, programmable logic devices, or other processing means. The processing operations performed by processor 1210 include the execution of an operating platform or operating system on which applications and/or device functions are executed. The processing operations include operations related to I/O (input/output) with a human user or with other devices, operations related to power management, and/or operations related to connecting the computing device 1200 to another device. The processing operations may also include operations related to audio I/O and/or display I/O.

In one embodiment, computing device 1200 includes audio subsystem 1220, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1200, or connected to the computing device 1200. In one embodiment, a user interacts with the computing device 1200 by providing audio commands that are received and processed by processor 1210.

Display subsystem 1230 represents hardware (e.g., display devices) and software (e.g., drivers) components that provide a visual and/or tactile display for a user to interact with the computing device 1200. Display subsystem 1230 includes display interface 1232, which includes the particular screen or hardware device used to provide a display to a user. In one embodiment, display interface 1232 includes logic separate from processor 1210 to perform at least some processing related to the display. In one embodiment, display subsystem 1230 includes a touch screen (or touch pad) device that provides both output and input to a user.

I/O controller 1240 represents hardware devices and software components related to interaction with a user. I/O controller 1240 is operable to manage hardware that is part of audio subsystem 1220 and/or display subsystem 1230. Additionally, I/O controller 1240 illustrates a connection point for additional devices that connect to computing device 1200 through which a user might interact with the system. For example, devices that can be attached to the computing device 1200 might include microphone devices, speaker or stereo systems, video systems or other display devices, keyboard or keypad devices, or other I/O devices for use with specific applications such as card readers or other devices.

As mentioned above, I/O controller 1240 can interact with audio subsystem 1220 and/or display subsystem 1230. For example, input through a microphone or other audio device can provide input or commands for one or more applications or functions of the computing device 1200. Additionally, audio output can be provided instead of, or in addition to display output. In another example, if display subsystem 1230 includes a touch screen, the display device also acts as an input device, which can be at least partially managed by I/O controller 1240. There can also be additional buttons or switches on the computing device 1200 to provide I/O functions managed by I/O controller 1240.

In one embodiment, I/O controller 1240 manages devices such as accelerometers, cameras, light sensors or other environmental sensors, or other hardware that can be included in the computing device 1200. The input can be part of direct user interaction, as well as providing environmental input to the system to influence its operations (such as filtering for noise, adjusting displays for brightness detection, applying a flash for a camera, or other features).

In one embodiment, computing device 1200 includes power management 1250 that manages battery power usage, charging of the battery, and features related to power saving operation. Memory subsystem 1260 includes memory devices for storing information in computing device 1200. Memory can include nonvolatile (state does not change if power to the memory device is interrupted) and/or volatile (state is indeterminate if power to the memory device is interrupted) memory devices. Memory subsystem 1260 can store application data, user data, music, photos, documents, or other data, as well as system data (whether long-term or temporary) related to the execution of the applications and functions of the computing device 1200.

Elements of embodiments are also provided as a machine-readable medium (e.g., memory 1260) for storing the computer-executable instructions. The machine-readable medium (e.g., memory 1260) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1270 includes hardware devices (e.g., wireless and/or wired connectors and communication hardware) and software components (e.g., drivers, protocol stacks) to enable the computing device 1200 to communicate with external devices. The computing device 1200 could be separate devices, such as other computing devices, wireless access points or base stations, as well as peripherals such as headsets, printers, or other devices.

Connectivity 1270 can include multiple different types of connectivity. To generalize, the computing device 1200 is illustrated with cellular connectivity 1272 and wireless connectivity 1274. Cellular connectivity 1272 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1274 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1280 include hardware interfaces and connectors, as well as software components (e.g., drivers, protocol stacks) to make peripheral connections. It will be understood that the computing device 1200 could both be a peripheral device (“to” 1282) to other computing devices, as well as have peripheral devices (“from” 1284) connected to it. The computing device 1200 commonly has a “docking” connector to connect to other computing devices for purposes such as managing (e.g., downloading and/or uploading, changing, synchronizing) content on computing device 1200. Additionally, a docking connector can allow computing device 1200 to connect to certain peripherals that allow the computing device 1200 to control content output, for example, to audiovisual or other systems.

In addition to a proprietary docking connector or other proprietary connection hardware, the computing device 1200 can make peripheral connections 1280 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a package substrate;
an integrated circuit device coupled with contacts on a surface of the package substrate;
underfill between the integrated circuit device and the surface of the package substrate;
thermal interface material on a surface of the integrated circuit device opposite the package substrate;
a heat spreader in contact with the thermal interface material; and
a material on a fillet of the underfill, the material adjacent to the thermal interface material.

2. The apparatus of claim 1, wherein the material is in contact with the heat spreader.

3. The apparatus of claim 1, wherein the material comprises a plurality of discrete segments laterally spaced apart along at least one edge of the integrated circuit device by less than 100 um.

4. The apparatus of claim 1, wherein the material extends a longitudinal length equal to at least one edge of the integrated circuit device.

5. The apparatus of claim 1, wherein the material has a height equal to at least one edge of the integrated circuit device.

6. The apparatus of claim 1, wherein the material is spaced apart from an edge of the integrated circuit device by a distance of between 100 um and 2000 um.

7. The apparatus of claim 1 wherein the material has a viscosity of between 20 and 100 pascal-seconds at room temperature.

8. The apparatus of claim 1 wherein the material has a modulus of less than 900 megapascals at room temperature.

9. The apparatus of claim 1 wherein the material has a thixotropic index of greater than 1.5.

10. The apparatus of claim 1, wherein the material comprises silicone resin with an oxide filler.

11. An integrated circuit device package comprising:
a package substrate;
an integrated circuit device coupled with contacts on a surface of the package substrate;
a passive circuit component on the surface of the package substrate conductively coupled with the integrated circuit device;
underfill between the integrated circuit device and the surface of the package substrate;
thermal interface material on a surface of the integrated circuit device opposite the package substrate;
a heat spreader in contact with the thermal interface material; and
a material on a fillet of the underfill, the material adjacent to the thermal interface material

12. The integrated circuit device package of claim 11 wherein the material fluctuates in height between the material being in contact with the heat spreader and the material being separated from the heat spreader.

13. The integrated circuit device package of claim 11, wherein the material comprises silicone resin with a titanium oxide filler at a concentration of between 10-20% by volume.

14. The integrated circuit device package of claim 11, wherein the material surrounds all edges of the integrated circuit device.

15. The integrated circuit device package of claim 11, wherein the fillet of the underfill comprises a concave surface that extends beyond an edge of the integrated circuit device to the surface of the package substrate, and the material protrudes from the concave surface.

16. The integrated circuit device package of claim 11, wherein the thermal interface material comprises a solder or a polymer.

17. A system comprising:
a system board;
a memory coupled with the system board; and
an integrated circuit device package coupled with the system board, the integrated circuit device package comprising:
a package substrate;
an integrated circuit device coupled with contacts on a surface of the package substrate;
a passive circuit component on the surface of the package substrate conductively coupled with the integrated circuit device;
underfill between the integrated circuit device and the surface of the package substrate;
thermal interface material on a surface of the integrated circuit device opposite the package substrate;
a heat spreader in contact with the thermal interface material; and
a material on a fillet of the underfill, the material adjacent to the thermal interface material

18. The system of claim 17, wherein the material is in contact with the heat spreader, the material having a first width at a junction with the heat spreader and a second width at a junction with the fillet of the underfill, the first width being greater than the second width.

19. The system of claim 17, wherein the thermal interface material extends beyond an edge of the integrated circuit device and contacts a portion of the underfill fillet between an edge of the integrated circuit device and the material, but is absent from an exterior side of the material opposite the integrated circuit device.

20. The system of claim 17, wherein the material has a transverse width of between 100 um and 400 um.

21. The system of claim 17, wherein the material comprises a polymer resin.

22. The system of claim 17, wherein the material fluctuates in height between the material being in contact with the heat spreader and the material being separated from the heat spreader.
